(19) United States
(12) Patent Application Publication
(10) Pub. No.: US 2012/0097208 A1
(43) Pub. Date: Apr. 26, 2012

(54) METHOD FOR THE PRODUCTION AND SERIES CONNECTION OF STRIP-SHAPED ELEMENTS ON A SUBSTRATE

(75) Inventors: Andreas Lambertz, Juelich (DE); Stefan Haas, Baesweiler (DE)

(73) Assignee: Forschungszentrum Juelich GmbH, juelich (DE)

(21) Appl. No.: 13/261,093

(22) PCT Filed: Jul. 1, 2010
(86) PCT No.: PCT/DE2010/000758

§ 371 Date: Dec. 20, 2011

(30) Foreign Application Priority Data
Jul. 3, 2009 (DE) 102009031592.6

(51) Int. Cl. H01L 31/042; H01L 27/10; H01L 21/768; H01L 31/18

(52) U.S. Cl. 136/244; 438/98; 257/499; 438/598; 257/E21.575; 257/E27.07; 257/E31.124

(57) ABSTRACT

Provided is a method for generating, and for connecting in series, stripe-shaped elements, wherein less space is required for the series connection as compared to the prior art.

The invention relates to a method for producing and for connecting in series stripe-shaped elements on a substrate, in particular to form a solar module, and to a solar module.

### PRIOR ART

The series connection of photovoltaic elements to form a solar module is used to combine light-induced energy that is generated in the elements, without generating a short circuit. To this end, a first electrical contact is usually conductively connected to a second electrical contact in two photovoltaic elements, wherein the contacts, which are also referred to as electrodes, are disposed on opposing sides of the photovoltaic element.

It is known from the prior art to apply a first electrical contact as a layer over the entire surface area of a substrate. The first contact layer is divided, starting from the surface and reaching down to the substrate, into several parallel stripes by way of a first structuring step. Following the first structuring step P1, the active semiconductor layers are applied to the entire surface area of the surface of the structured first contact, whereby the trenches located therein are filled. Thereafter, in a second structuring process P2, the semiconductor layers are divided, starting from the surfaces of the semiconductor layers and up to the surface of the first electrical contact, into several stripes. This second structuring process P2 takes place closely adjacent to, and parallel to, the first structuring process P1 and the stripe-shaped divisions of the first electrical contact. Then, a second electrical contact layer is provided on the surface of the photovoltaic element that has been divided into stripes, and is in turn divided into stripes, on the structured first electrical contact and the structured semiconductor layers. In the third structuring process P3, the second electrical contact, starting from the surface thereof and up to the surface of the semiconductor layers, is divided into several parallel stripes. P3 takes place as close as possible adjacent to, and parallel to, the second structuring process P2, and parallel to, but further spaced apart from, the first structuring process P1.

Starting from the surface of the second electrical contact, a connection is thus established to the first electrical contact and the series connection is established by filling the trenches in the photovoltaic elements located beneath.

The disadvantage of this standard method is a low energy conversion rate from the series-connected photovoltaic elements of the solar module.

### PROBLEM AND SOLUTION OF THE INVENTION

It is the object of the invention to provide a method for producing, and for connecting in series, stripe-shaped elements, in particular to form a solar module, which results in a higher energy conversion rate. It is another object of the invention to provide a corresponding solar module having an increased energy conversion rate.

The object is achieved by a method according to claim 1 and by a layer structure, and by a solar module according to the additional independent claims. Advantageous embodiments will be apparent from the dependent claims.

To begin with, a plurality of more or less stripe-shaped first electrical contact layers, which are preferably disposed parallel to one another, are generated on a substrate or superstrate.

The substrate can be freely selected, for example, from all substrates or superstrates that are common in solar cell technology, in particular thin-film solar cell technology and thin-film technology, such as metal foils made of steel or aluminum (substrate). Glass or plastic films, for example, are used as the superstrate.

The substrate may comprise functional layers for improved light scatter or for improved epitaxial growth of the contact layer on the carrier.

A material such as Al/ZnO or Ag/ZnO (substrate) or ZnO, SnO₂ or ITO (superstrate) can be selected for the first electrical contact layer.

The stripe-shaped electrical contact layers are insulated in a stripe-shaped manner over the length of the elements by first trenches, which are arranged parallel to one another, up to the surface of the substrate. However, a limiting frame may be provided for the elements.

The length of the substrate (L) runs at least over the length of the elements (L).

The stripe-shaped first contact layers can be generated on the substrate or superstrate by way of lithographic methods using masking and spraying or etching methods, for example. They can also be generated by first applying a contact layer over the entire surface area of the substrate and then structuring the same, for example by way of laser ablation or masking and etching methods. Other methods and method combinations are possible.

Thereafter the semiconductor layers are generated on the stripe-shaped first electrical contact layers, or in the first trenches, on such a layer structure comprising a substrate and first electrical contact layers.

The semiconductor layers are designed with regional, and preferably punctiform, recesses at the respective edges of each first trench.

The surfaces of the first electrical contact layers are exposed therein. This is used for subsequent contacting for connecting adjoining stripe-shaped elements in series.

To this end, a plurality of stripe-shaped second electrical contact layers, which are preferably disposed parallel to one another, are provided on the semiconductor layers. The regional cut-outs in the semiconductor layers are thus advantageously filled. This creates corresponding regional contacts of each second electrical contact layer of an element (A) to each first electrical contact layer of an adjoining element (B).

Second trenches that are provided over the length of the elements are advantageously used to insulate the second electrical contact layers and, for this purpose, are created therein. Underneath, the surface of the first electrical contact layer may be exposed, or the semiconductor layers may be exposed.

The first trenches for insulating the first electrical contact layers and/or the second trenches for insulating the second electrical contact layers advantageously run around the regional cut-outs with meandering or angled sections, so that, when seen from above, each cut-out is provided between a first trench and a second trench, or the trenches are formed around the cut-outs, whereby the adjoining elements are connected in series.

This achieves the object of the invention because the majority of semiconductor layers can be utilized in a space-saving manner. As compared to the prior art, considerably less surface area is required for the series connection, because the state of the art is based on structurings that are placed next to one another. The region located between these structurings is not accessible for power generation.

The number of meandering or angled sections of the first and/or second trenches should correspond to the number of cut-outs. Both the first and the second trenches can comprise meandering sections.

So as to create the stripe-shaped elements, a second trench is created above each first trench and is associated with the same. Over the length of the elements, 2 to 50, preferably 5 to 30, and more particularly 10 to 20 cut-outs are generated along the edges of the trenches. The length of the substrate is then preferably approximately 10 cm. More cut-outs should be formed in larger substrates. The smaller the surface areas of the cut-outs, the more space is preserved for power generation.

Selecting the distance of the cut-outs from one another will depend, amongst others, on the size thereof. Preferably a distance of 0.2 millimeters to 100 millimeters, and more particularly 1.5 millimeters to 10 millimeters, can be selected along the edge of a trench.

The lateral distance between a first and an associated second trench, as it is shown in the figures, can amount up to 2 millimeters for insulating adjoining contact layers. It should not be selected so as to be excessively large.

Except in the regions of the cut-outs, the first trench should particularly advantageously be arranged directly above the second trench, when seen from above, so that the majority of both trenches together runs congruently over the length of the elements.

So as to render the majority of semiconductor layers usable for power generation, the regional cut-outs should preferably be produced in a punctiform manner, for example having a surface area of up to 1 mm², and more particularly up to 0.01 mm². The regional cut-outs for the contacts are thus comparatively small so as to be able to fully utilize the semiconductor layers located between the cut-outs for power generation.

Advantageously, laser ablation may also be employed to generate the first and/or second trenches and/or the cut-outs.

It is also possible to provide masks that are designed in accordance with the created structures in order to produce the first and/or second trenches and/or the cut-outs and to then conduct etching, so as to generate the trenches or cut-outs. Any PVD or CVD method, or spraying method or printing method, may be applied for depositing layers, as well as ink jet printing methods in particular.

An etching method can likewise be selected to produce the first and/or second trenches and/or the cut-outs.

It is particularly advantageous that materials for the semiconductor layers and the contact layers be provided, so that these are able to create stripe-shaped photovoltaic elements over the length of the substrate, for example a glass substrate and a TCO (transparent conductive oxide) as a first electrical contact layer on the substrate.

At least one n-i-p or p-i-n structure can be provided as the active semiconductor layer or layers on the first electrical contact layers.

The second electrical contact layer can be created with ZnO/Ag in a stripe-shaped manner.

The layer structure thus formed comprises a substrate, comprising a plurality of stripe-shaped first electrical contact layers, which are preferably disposed parallel to one another, over the length of the substrate, and semiconducting layers, which are provided over the first electrical contact layers, and further a plurality of stripe-shaped second electrical contact layers, which are preferably disposed parallel to one another, over the length of the substrate, these second electrical contact layers being provided on the semiconducting layers.

The second electrical contact layers make contact with the first electrical contact layers via regional cut-outs in the semiconducting layers. The regional cut-outs do not run over the length (L) of the elements, as in the prior art. Additionally, the edges of the regional cut-outs are formed exclusively by material of the semiconducting layers. First trenches are provided in the first electrical contact layers, and second trenches are provided in the second electrical contact layers, so as to insulate the first and second electrical contact layers from one another, wherein meandering sections of the first and/or the second trenches are closely guided around the cut-outs.

When seen from above, the second electrical contact layers and/or the first electrical contact layers comprise meandering, for example angled or rounded, regions around the regional cut-outs. Because the first trenches and the second trenches, when seen from above, are provided closely or tightly, and preferably even substantially congruently, which is to say without lateral offset, on top of one another, all regions between the cut-outs over the length of the elements can be utilized for power generation. The regional cut-outs are created between respective first and second trenches.

A solar module can have this layer structure. To this end, the second electrical contact layers and first electrical contact layers and the semiconducting layers comprise materials that create photovoltaic elements (A, B, C) over the length of the substrate.

According to a special method for producing, and for connecting in series, photovoltaic elements (A, B, C) on a substrate, initially a first electrical contact is provided as a layer over the entire surface area of the substrate and, by generating parallel first trenches therein, is divided in a stripe-shaped manner up to the surface of the substrate. Semiconductor layers are then provided on the first electrical contact, or in the first trenches, and regional cut-outs are generated by removing the semiconductor layers parallel to an edge of each first trench.

Then, a second electrical contact should be provided on the semiconductor layers, preferably over the entire surface area, whereby the cut-outs are filled. Except for the respective regions adjoining the cut-outs, the second electrical contact and the semiconductor layers are removed at the locations of the first trenches, whereby a number of photovoltaic elements (A, B, C) which corresponds to the number of trenches are electrically insulated from one another. In addition, at least the second electrical contact layer, and optionally the active semiconductor layers, are removed around the remaining region of the cut-outs, up to the surface of the first electrical contact layer, whereby the first contact of a photovoltaic element (B) is connected in series by the second contact of an adjoining element (A) by way of a plurality of, preferably punctiform, contacts.

It is particularly advantageous for the ratio of the surface area of the active series-connected semiconductor layers to the total surface area of the module of a solar cell module according to the invention to be at least 98%, preferably more than 98.5%, and more particularly 99% or more.

It was found, within the scope of the invention, that when using the method according to the prior art, large regions, which is to say those in which structuring steps are carried out over the length of the elements, and further the entire region between structuring steps one and two, and between structuring steps two and three, can no longer be utilized for energy conversion. It was found that the potential output of a solar module is thereby unnecessarily reduced.

It was further found that a path toward a smaller overall surface area that incurs losses can lead to a higher energy conversion rate.

For this purpose, a photovoltaic element is selectively removed in a second structuring process P2 in a locally punctiform manner, starting from the surfaces of the semiconductor layers, up to the surface of the first electrical contact. This second structuring process P2 takes place as close as possible adjacent to, and parallel to, the parallel first trenches in the first electrical contact. It is also possible to place these punctiform cut-outs directly on the structure edges of the trenches.

In a further step, a second electrical contact layer is then provided on the active semiconductor layers and in the punctiform recesses, for example over the entire surface area and on the side of the semiconductor layers that is opposite of the first contact layer. This results in a layer structure, comprising a substrate, a first electrical contact provided thereon, a p-i-n or p-i-n-p-i-n or comparable structure provided thereon, and a second electrical contact provided thereon.

Thereafter, this second electrical contact and the semiconductor layers are divided into stripes by a third structuring step P3. The trenches required for this are preferably generated at the locations of the first trenches. To this end, the second contact and the active semiconductor layers are preferably generated on the trenches of the first structuring step P1, provided that no cut-out is present in the active semiconductor material next to the trench created by the second structuring step P2. The third structuring extends on the three sides next to the contacting hole which do not face the trench created by the first structuring P1, in the regions in which a cut-out is located for implementing the contact between the first electrical contact and second electrical contact. The structuring trenches must result in a continuous line so as to prevent the photovoltaic elements from electrically short-circuiting.

The advantage in restructuring the interconnecting regions, as compared to the prior art, is again that a smaller surface area is required for the series connection, whereby greater conversion efficiency can be achieved. The distances of the cut-outs for implementing the contacting of the first electrical contact layer with the second electrical contact layer from one another are adjusted so that the overall losses caused by the interconnection, which include the conducting losses caused by the electrical contact layers and the surface area losses caused by the material ablation and interconnection, are minimized.

The invention will be described in more detail hereafter based on six exemplary embodiments and the accompanying figures, without thereby limiting the invention.

The reference symbols A, B, C denote the photovoltaic elements, and the reference symbol L denotes the length of the elements or of the substrate.

### First Exemplary Embodiment

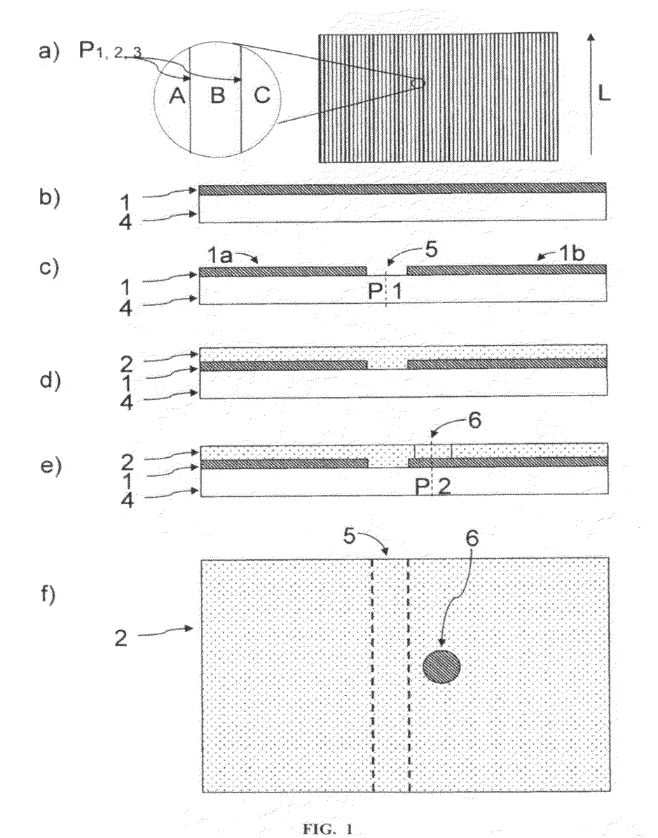

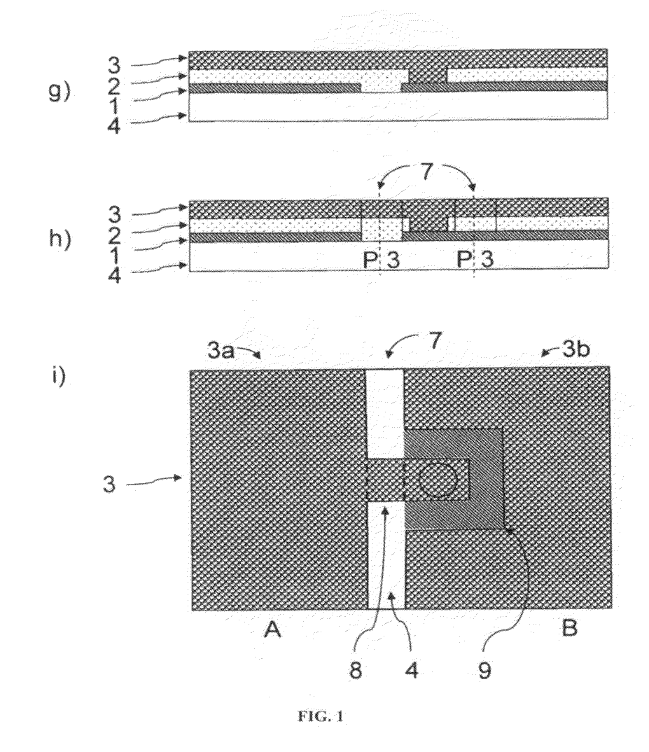

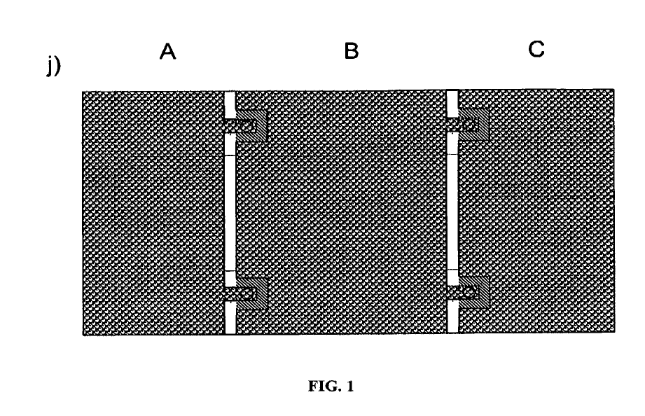

FIG. 1 shows the production and punctiform series-connection of the photovoltaic elements A, B, C to form a functional solar module, in which the structuring of the active semiconductor layers 6 is provided in a punctiform manner, parallel to the first structuring trench 5.

FIG. 1a) shows a top view of several stripe-shaped photovoltaic elements in a solar module. An enlarged detail shows the respective three stripes A, B, C disposed parallel to one another. The designations P1-3 in the figures denote the approximate positions and numbers of structurings of each trench or each punctiform semiconductor structuring. The stripe-shaped photovoltaic elements A, B, C are composed of the first and second electrical contact layers 1, 3 and the semiconductor layers 2 interposed between them.

FIG. 1b) shows the starting point of the method. A first electrical TCO (transparent conductive oxide) contact layer 1 is provided over the entire surface area of a superstrate 4, which serves as the substrate, having a thickness of approximately 1 millimeter.

Glass having a base area of 100 cm² has been selected as the substrate 4. The first electrical contact layer 1 comprising ZnO was deposited thereon in a first deposition process. A functional layer is provided between the substrate 4 and ZnO and associated with the substrate (not shown) to improve the structure formation of the ZnO. The first electrical contact layer 1 comprising zinc oxide, which has been textured by way of a wet-chemical process, has a thickness of approximately 800 nm.

In a first structuring process P1 (FIG. 1c)), material is removed from the first electrical contact layer 1 by way of laser ablation, whereby the surface of the substrate 4 is exposed in the parallel trenches 5. This structuring process P1 is carried out consecutively for all photovoltaic elements A, B, C. The laser is guided for this purpose over the surface of the substrate 4 using a relative movement. The distance and output power are adjusted so that material of the layers 1 is removed.

The laser that is employed is an Nd:YVO₄ laser from Rofin, of the RSY 20E THG type, having a wavelength of 355 nm. This wavelength is specific to the ablation of material of the contact layer 1. An average output power of 300 mW at a pulse repetition rate of 15 kHz is selected. The velocity of the relative movement between the laser beam and substrate is 250 mm/s. The duration of the individual pulses is approximately 13 ns. The laser radiation is focused on the layer side of the substrate 4 using a focusing unit that has a focal distance of 100 mm. To this end, the beam is conducted, from the substrate side, at the layer 1 to be ablated through the transparent substrate 4. The intensity distribution of the focused beam is substantially 2-dimensional, rotationally symmetrical and Gaussian, wherein each pulse produces a circular ablation having a diameter of approximately 35 μm. Following the first structuring process P1, the first electrical contact layer 1 is separated by parallel first trenches 5 down to the substrate 4. As a result, the stripe-shaped, parallel first electrical contact layers of the photovoltaic elements A, B, C are present on the substrate 4 electrically insulated from one another by the trenches 5. A plurality of first trenches 5 for separating the photovoltaic elements A, B, C are thus generated (see FIG. 1a: vertical stripes in the module on the right).

Following the structuring process P1, a respective trench 5 is located between two directly adjoining photovoltaic elements A, B or C, B. The structuring process P1 is carried out by way of computer-assisted control. The structuring process P1 is repeated a number of times equal to the number of photovoltaic elements that are to be generated. For an edge length of the glass substrate 4 of 10×10 cm, approximately 16 parallel trenches 5 are generated, so that a stripe A, B, or C has a width of approximately 0.5 cm.

Thereafter, the entire substrate 4 is covered with the microcrystalline p-i-n solar cell 2 comprising silicon on the side on which the first electrical contact layer 1 is located, whereby the first electrical contact layer 1 and the trenches 5 are covered or filled with the silicon of the layers 2 (FIG. 1d)). The thickness of the microcrystalline p-i-n layer stack 2, which serves as the active semiconductor layer 2, is approximately 1300 nm.

The active semiconductor layers 2 are ablated up to the surface of the first electrical contact layer 1 (FIG. 1e)) by means of a second structuring process along the dotted line P2 so as to create punctiform cut-outs 6. To this end, for each trench, the respective material on the right next to the right edge of the trenches 5 which was created by the first structuring process P1 is ablated so as to be able to generate punctiform contacts to the photovoltaic elements disposed to the left of the trenches, in the present case from element A to element B (FIGS. 1f and 1i)).

As differs from the first structuring process P1, no stripe-shaped ablation of the active semiconductor layers 2, generating a trench that extends over the length of the element up to the surface of the first electrical contact layer 1, is performed.

The laser that is employed is an Nd:YVO₄ laser from Rofin, of the RSY 20E SHG type. The wavelength of the laser is 532 nm. This wavelength is specific to the ablation of the materials of the semiconductor layers 2. Because both the substrate 4 and the first electrical contact layer 1 are highly transparent at the selected specific wavelength of 532 nm, selective ablation of the active semiconductor layers 2 is assured. The energy for each laser pulse is selected to be approximately 40 μJ. The pulse repetition rate is 533 Hz. The velocity of the relative movement between the laser beam and substrate is 800 mm/s. This results in a distance of the holes from each other of approximately 1.5 mm. The duration of the individual pulses is approximately 13 ns. The laser radiation is focused on the layer side of the substrate 4 using a focusing unit having a focal distance of 300 mm. To this end, the beam is conducted, from the substrate side 4, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm.

This results in the stripe-shaped, parallel photovoltaic elements A, B, C on the substrate 4, wherein punctiform cut-outs 6 exist in the subsequently active semiconductor layers 2 so as to implement a punctiform series connection (FIG. 1f). A plurality of openings 6 for contacting the first electrical contact layer 1 of the photovoltaic elements A, B, C are thus generated. The structuring process P2 is repeated a number of times equal to the number of photovoltaic elements that are present.

Then, a second electrical contact 3 is applied. The second electrical contact 3 is provided on the active semiconductor layer 2. A layer system comprising 80 nm of zinc oxide in combination with a 200 nm thick silver layer is selected as the second electrical contact layer 3. Here, first the zinc oxide layer, followed by the silver layer, are present on the silicon layer stack 2 on the side of the second electrical contact layer.

A structuring process P3 then follows. The trenches 7, which were generated by the structuring process P3, are created so that the second electrical contact layer 3 and the active semiconductor layers 2 located beneath are removed at the location of the first trenches 5, at those sites at which no cut-out 6 for contacting the first electrical contact layer is present.

Moreover, the second electrical contact layer 3 and the active semiconductor layers 2 located beneath are removed in the regions in which cut-outs 6 are present, so that the material of the semiconductor layers 2 and of the second electrical contact 3 is removed beneath, above and to the right of the cut-outs 6. The individual regions between two photovoltaic elements A, B in which material was removed in this structuring step are linked so as to produce continuous insulation of the second contact of two adjoining regions A, B. This subsequently prevents two adjoining photovoltaic elements A, B from short-circuiting (FIGS. 1h, i)).

An Nd:YVO₄ laser from Rofin, of the RSY 20E SHG type, is employed as the laser for ablating the material from layers 2 and 3. The wavelength of the laser is 532 nm. This wavelength is specific to the ablation of materials of the two layers 2, 3. An average output power of 410 mW at a pulse repetition rate of 11 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted, from the substrate side, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm. This creates the approximately U-shaped insulations 9 around the cut-outs 6 and the contact bridges 8 for the punctiform series connection of the elements.

Because this structuring process P3 is once again carried out along the entire stripe, a trench 7 is provided which is located substantially on the trench 5 and is offset from the first trench 5 by a very small degree. The structuring process P3 is repeated as often as the structuring processes P1 and P2 are, and as often as the number of layers 1, 2, 3 present in a plurality of stripe-shaped, parallel photovoltaic elements, separated by the trenches 5 and 7 and connected in series with one another by the cut-outs 6.

A cut-out 6 is required approximately every 1.5 millimeters for a surface area of 10×10 cm² and approximately 16 trenches 7.

The advantage of this exemplary embodiment, as compared to the prior art, is that a much smaller surface area is required for the series connection, whereby greater conversion efficiency can be achieved. The distance of the holes 6 from each other is adjusted so that the overall losses caused by the interconnection, which result from the conducting losses caused by the electrical contact layers 1 and 3 and surface area losses caused by the material ablation and interconnection, are minimized.

### Second Exemplary Embodiment

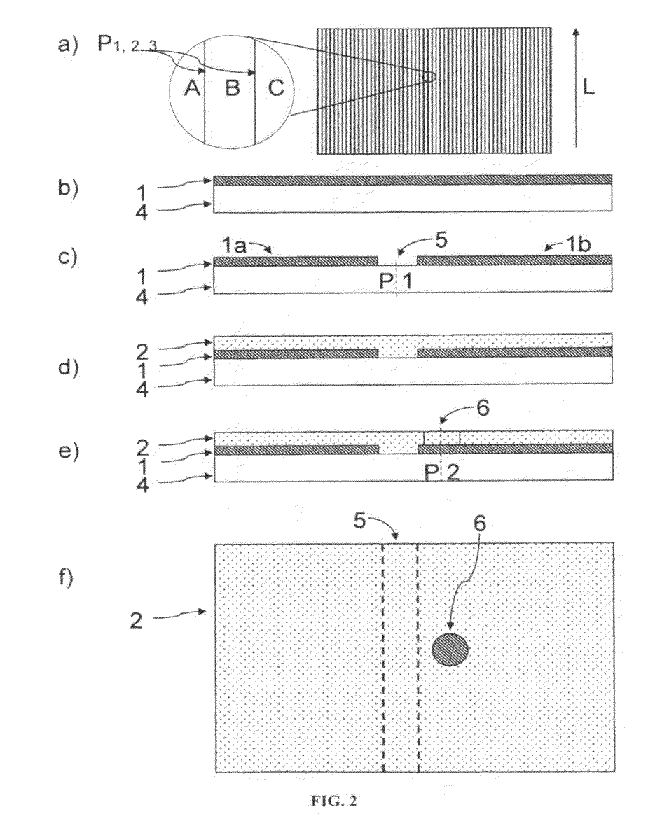

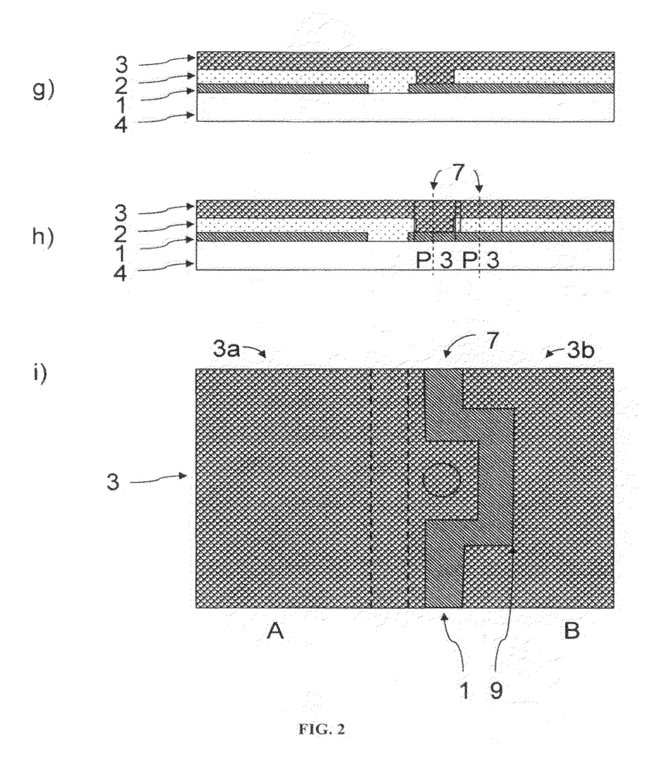

FIG. 2 shows the production and punctiform series-connection of the photovoltaic elements A, B, C to form a functional solar module, in which the structuring of the active semiconductor layers 6 is provided in a punctiform manner, parallel to the first structuring trench 5.

FIG. 2a) shows a top view of several stripe-shaped photovoltaic elements in a solar module. An enlarged detail shows the respective three stripes A, B, C disposed parallel to one another. The designations P1-3 in the figures denote the approximate positions and numbers of structurings of each trench or each punctiform semiconductor structuring. The stripe-shaped photovoltaic elements A, B, C are composed of the first and second electrical contact layers 1, 3 and the semiconductor layers 2 interposed between them.

FIG. 2b) shows the starting point of the method. A first electrical TCO (transparent conductive oxide) contact layer 1 is provided over the entire surface area of a superstrate 4, which serves as the substrate, having a thickness of approximately 1 millimeter.

Glass having a base area of 100 cm² was selected as the substrate 4. The first electrical contact layer 1 comprising ZnO was deposited thereon in a first deposition process. A functional layer is provided between the substrate 4 and ZnO and associated with the substrate (not shown) to improve the structuring of the ZnO.

A glass panel measuring 10×10 cm² is used as the base for the exemplary embodiment. A first electrical contact layer 1 comprising zinc oxide, which has been textured by way of a wet-chemical process and has a thickness of approximately 800 nm, is present on the glass substrate.

In a first structuring process P1 (FIG. 2c)), material is removed from the first electrical contact layer 1 by way of laser ablation, whereby the surface of the substrate 4 in the parallel trenches 5 is exposed. This structuring process P1 is carried out consecutively for all photovoltaic elements A, B, C. The laser is guided for this purpose over the surface of the substrate 4 using a relative movement. The distance and output power are adjusted so that the material of the layers 1 is removed.

The laser that is employed is an Nd:YVO₄ laser from Rofin, of the RSY 20E THG type, having a wavelength of 355 nm. This wavelength is specific to the ablation of material of the contact layer 1. An average output power of 300 mW at a pulse repetition rate of 15 kHz is selected. The velocity of the relative movement between the laser beam and substrate is 250 mm/s. The duration of the individual pulses is approximately 13 ns. The laser radiation is focused on the layer side of the substrate 4 using a focusing unit that has a focal distance of 100 mm. To this end, the beam is conducted, from the substrate side, at the layer 1 to be ablated through the transparent substrate 4. The intensity distribution of the focused beam is substantially 2-dimensional, rotationally symmetrical and Gaussian, wherein each pulse produces a circular ablation having a diameter of approximately 35 μm. Following the first structuring process P1, the first electrical contact layer 1 is separated by parallel first trenches 5 down to the substrate 4. As a result, the stripe-shaped, parallel first electrical contact layers of the photovoltaic elements A, B, C are present on the substrate 4 electrically insulated from one another by the trenches 5. A plurality of first trenches 5 for separating the photovoltaic elements A, B, C are thus created (see FIG. 2a: vertical stripes in the module on the right).

Following the structuring process P1, a respective trench 5 is located between two directly adjoining photovoltaic elements A, B or C, B. The structuring process P1 is carried out by way of computer-assisted control. The structuring process P1 is repeated a number of times equal to the number of photovoltaic elements that are to be generated. For an edge length of the glass substrate 4 of 10×10 cm, approximately 16 parallel trenches 5 are generated, so that a stripe A, B, or C has a width of approximately 0.5 cm.

Thereafter, the entire substrate 4 is covered with a microcrystalline p-i-n solar cell 2, comprising silicon on the side on which the first electrical contact layer 1 is located, whereby the first electrical contact layer 1 and the trenches 5 are covered or filled with the silicon of the layers 2 (FIG. 2d)). The overall thickness of the microcrystalline p-i-n layer stack 2, which serves as the active semiconductor layer 2, is approximately 1300 nm.

The active semiconductor layers 2 are ablated up to the surface of the first electrical contact layer 1 (FIG. 2e)) by means of a second structuring process along the dotted line P2 so as to generate punctiform cut-outs. To this end, for each trench the respective material on the right next to the right edge of the trenches 5 which was created by the first structuring process P1 is ablated so as to be able to generate punctiform contacts to the photovoltaic elements disposed to the left of the trenches, in the present case from element A to element B (FIG. 2f)).

As differs from the first structuring process P1, no stripe-shaped ablation of the active semiconductor layers 2 over the length of the element (as in the prior art), creating a continuous trench up to the surface of the first electrical contact layer 1, is performed.

The laser that is employed is an Nd:YVO₄ laser from Rofin, of the RSY 20E SHG type. The wavelength of the laser is 532 nm. This wavelength is specific to the ablation of the materials of the semiconductor layers 2. Because both the substrate 4 and the first electrical contact layer 1 are highly transparent at the selected specific wavelength of 532 nm, selective ablation of the active semiconductor layers 2 is assured. The energy for each laser pulse is selected to be approximately 40 μJ. The pulse repetition rate is 800 Hz. The velocity of the relative movement between the laser beam and substrate is 800 mm/s. This results in a distance of the holes from one another of 1 mm. The duration of the individual pulses is approximately 13 ns. The laser radiation is focused on the layer side of the substrate 4 using a focusing unit that has a focal distance of 300 mm. To this end, the beam is conducted, from the substrate side 4, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm.

This results in the stripe-shaped, parallel photovoltaic elements A, B, C on the substrate 4, wherein punctiform cut-outs 6 exist in the subsequently active semiconductor layers 2, so as to implement a punctiform series connection (FIG. 2f)). A plurality of openings 6 for contacting the first electrical contact layer 1 of the photovoltaic elements A, B, C are thus generated. The structuring process P2 is repeated a number of times equal to the number of photovoltaic elements that are present.

Then, a second electrical contact 3 is applied. The second electrical contact 3 is provided on the active semiconductor layer 2. A layer system, comprising 80 nm of zinc oxide in combination with a 200 nm thick silver layer, is selected as the second electrical contact layer 3. Here, first the zinc oxide layer, followed by the silver layer, are present on the silicon layer stack 2 on the side of the second electrical contact layer (FIG. 2g)).

A structuring process P3 then follows. The trenches 7, which were produced by the structuring process P3, are generated so that the second electrical contact layer 3, and the active semiconductor layers 2 located beneath, are removed slightly offset from the location of the first trenches 5, at those sites at which no cut-out 6 for contacting the first electrical contact layer is present. To this end, the trenches 7 are offset by approximately 150 μm in the direction of the cut-outs 6, with respect to the trenches 5 (FIGS. 2h, i)).

Moreover, the second electrical contact layer 3 and the active semiconductor layers 2 located beneath are removed in the regions in which cut-outs 6 are present, so that the material of the semiconductor layers 2 and of the second electrical contact 3 is removed beneath, above and to the right of the cut-outs 6. The individual regions between two photovoltaic elements A, B in which material was removed in this structuring step are linked so as to produce continuous insulation of the second contact of two adjoining regions A, B. This subsequently prevents two adjoining photovoltaic elements A, B from short-circuiting.

An Nd:YVO₄ laser from Rofin, of the RSY 20E SHG type, is employed as the laser for ablating the material from layers 2 and 3. The wavelength of the laser is 532 nm. This wavelength is specific to the ablation of materials of the two layers 2, 3. An average output power of 410 mW at a pulse repetition rate of 11 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted, from the substrate side, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm. This creates the approximately U-shaped insulations 9 around the cut-outs for the punctiform series connection of the elements.

Because this structuring process P3 is again carried out along the entire stripe, a trench 7 is provided which is offset from the first trench 5. The structuring process P3 is repeated as often as the structuring processes P1 and P2 are, and as often as the number of layers 1, 2, 3 present in a plurality of stripe-shaped, parallel photovoltaic elements, separated by the trenches 5 and 7 and connected in series with one another by the cut-outs 6.

A cut-out 6 is required approximately every 1 millimeter for a surface area of 10×10 cm² and approximately 16 trenches 7.

The advantage of this exemplary embodiment, as compared to the prior art, is that a smaller surface area is required for the series connection, whereby greater conversion efficiency can be achieved. The distance of the holes 6 from one another is adjusted so that the overall losses caused by the interconnection, which result from the conducting losses caused by the electrical contact layers 1 and 3 and surface area losses caused by the material ablation and interconnection, are minimized.

### Third Exemplary Embodiment

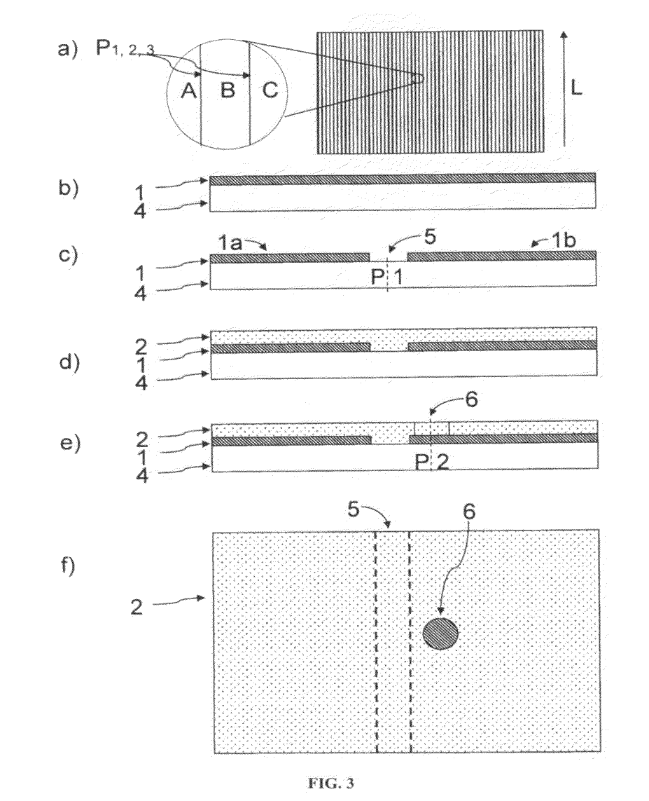

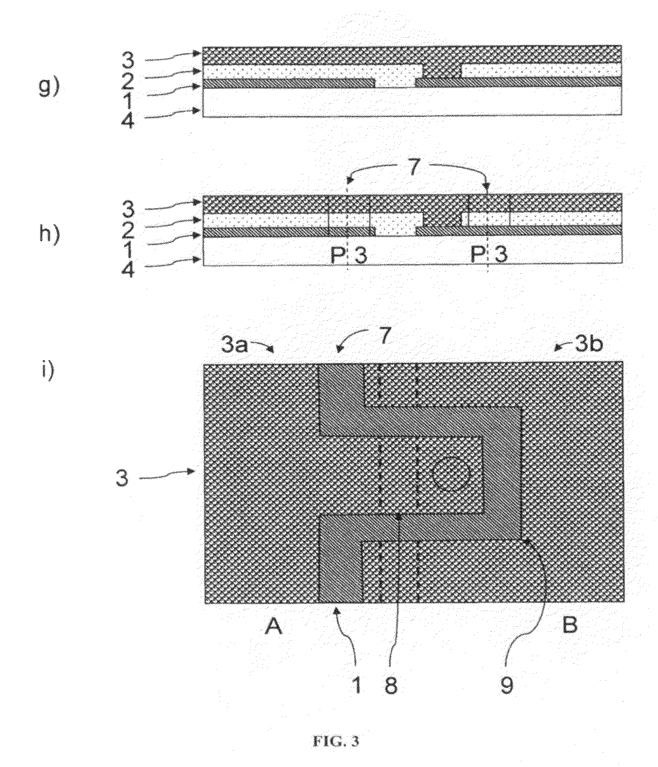

FIG. 3 shows the production and punctiform series-connection of the photovoltaic elements A, B, C to form a functional solar module, in which the structuring of the active semiconductor layers 6 is provided in a punctiform manner, parallel to the first structuring trench 5.

FIG. 3a) shows a top view of several stripe-shaped photovoltaic elements in a solar module. An enlarged detail shows the respective three stripes A, B, C disposed parallel to one another. The designations P1-3 in the figures denote the approximate positions and numbers of structurings of each trench or each punctiform semiconductor structuring. The stripe-shaped photovoltaic elements A, B, C are composed of the first and second electrical contact layers 1, 3 and the semiconductor layers 2 interposed between them.

FIG. 3b) shows the starting point of the method. A first electrical TCO (transparent conductive oxide) contact layer 1 is provided over the entire surface area of a superstrate 4, which serves as the substrate, having a thickness of approximately 1 millimeter.

Glass having a base area of 100 cm² has been selected as the substrate 4. The first electrical contact layer 1 comprising ZnO was deposited thereon in a first deposition process. A functional layer is provided between the substrate 4 and ZnO and is associated with the substrate (not shown) for improving the structuring of the ZnO.

A glass panel measuring 10×10 cm² is used as the base for the exemplary embodiment. A first electrical contact layer 1 comprising zinc oxide, which has been textured by way of a wet-chemical process and has a thickness of approximately 800 nm, is present on the glass substrate.

In a first structuring process P1 (FIG. 3c)), material is removed from the first electrical contact layer 1 by way of laser ablation, whereby the surface of the substrate 4, in the parallel trenches 5, is exposed. This structuring process P1 is carried out consecutively for all the photovoltaic elements A, B, C. The laser is guided for this purpose over the surface of the substrate 4 using a relative movement. The distance and output power are adjusted so that material of the layers 1 is removed.

The laser that is employed is an Nd:YVO₄ laser from Rofin, of the RSY 20E THG type, having a wavelength of 355 nm. This wavelength is specific to the ablation of material of the contact layer 1. An average output power of 300 mW at a pulse repetition rate of 15 kHz is selected. The velocity of the relative movement between the laser beam and substrate is 250 mm/s. The duration of the individual pulses is approximately 13 ns. The laser radiation is focused on the layer side of the substrate 4 using a focusing unit that has a focal distance of 100 mm. To this end, the beam is conducted, from the substrate side, at the layer 1 to be ablated through the transparent substrate 4. The intensity distribution of the focused beam is substantially 2-dimensional, rotationally symmetrical and Gaussian, wherein each pulse produces a circular ablation having a diameter of approximately 35 μm. Following the first structuring process P1, the first electrical contact layer 1 is separated by parallel first trenches 5 down to the substrate 4. As a result, the stripe-shaped, parallel first electrical contact layers of the photovoltaic elements A, B, C are present on the substrate 4 electrically insulated from one another by the trenches 5. A plurality of first trenches 5 for separating the photovoltaic elements A, B, C are thus created (see FIG. 3a: vertical stripes in the module on the right).

Following the structuring process P1, a respective trench 5 is located between two directly adjoining photovoltaic elements A, B or C, B. The structuring process P1 is carried out by way of computer-assisted control. The structuring process P1 is repeated a number of times equal to the number of photovoltaic elements that are to be generated. For an edge length of the glass substrate 4 of 10×10 cm, approximately 16 parallel trenches 5 are generated, so that a stripe A, B, or C has a width of approximately 0.5 cm.

Thereafter, the entire substrate 4 is covered with a microcrystalline p-i-n solar cell 2 comprising silicon on the side on which the first electrical contact layer 1 is located, whereby the first electrical contact layer 1 and the trenches 5 are covered or filled with the silicon of the layers 2 (FIG. 3d)). The overall thickness of the microcrystalline p-i-n layer stack 2, which serves as the active semiconductor layer 2, is approximately 1300 nm.

The active semiconductor layers 2 are ablated up to the surface of the first electrical contact layer 1 (FIG. 3e)) by means of a second structuring process along the dotted line P2 so as to generate punctiform cut-outs. To this end, for each trench the respective material on the right next to the right edge of the trenches 5, which was created by the first structuring process P1, is ablated so as to be able to generate punctiform contacts to the photovoltaic elements disposed to the left of the trenches, in the present case from element A to element B (FIG. 3f)).

As differs from the first structuring process P1, no stripe-shaped ablation of the active semiconductor layers 2, creating a continuous trench up to the surface of the first electrical contact layer 1, is performed.

The laser that is employed is an Nd:YVO₄ laser from Rofin, of the RSY 20E SHG type. The wavelength of the laser is 532 nm. This wavelength is specific to the ablation of the materials of the semiconductor layers 2. Because both the substrate 4 and the first electrical contact layer 1 are highly transparent at the selected specific wavelength of 532 nm, selective ablation of the active semiconductor layers 2 is assured. The energy for each laser pulse is selected to be approximately 40 μJ. The pulse repetition rate is 533 Hz. The velocity of the relative movement between the laser beam and substrate is 800 mm/s. This results in a distance of the holes from each other of 1.5 mm. The duration of the individual pulses is approximately 13 ns. The laser radiation is focused on the layer side of the substrate 4 using a focusing unit that has a focal distance of 300 mm. To this end, the beam is conducted from the substrate side 4 through the transparent substrate 4 at the layer to be ablated. The intensity distribution of the focused beam is substantially 2-dimensional, rotationally symmetrical and Gaussian, wherein each pulse produces a circular ablation having a diameter of approximately 70 μm.

This results in the stripe-shaped, parallel photovoltaic elements A, B, C on the substrate 4, wherein punctiform cut-outs 6 exist in the subsequently active semiconductor layers 2 so as to implement a punctiform series connection (FIG. 3f)). A plurality of openings 6 for contacting the first electrical contact layer 1 of the photovoltaic elements A, B, C are thus generated. The structuring process P2 is repeated a number of times equal to the number of photovoltaic elements that are present.

Then, a second electrical contact 3 is applied. The second electrical contact 3 is provided on the active semiconductor layer 2. A layer system comprising 80 nm of zinc oxide in combination with a 200 nm thick silver layer is selected as the second electrical contact layer 3. Here, first the zinc oxide layer, followed by the silver layer, are present on the silicon layer stack 2 on the side of the second electrical contact layer.

A structuring process P3 then follows. The trenches 7, which were produced by the structuring process P3, are generated so that the second electrical contact layer 3 and the active semiconductor layers 2 located beneath are removed slightly offset from the location of the first trenches 5, at those sites at which no cut-out 6 for contacting the first electrical contact layer is present. To this end, the trenches 7 are offset by approximately 150 μm with respect to the trenches 5, counter to the direction of offset of the cut-outs 6.

Moreover, the second electrical contact layer 3 and the active semiconductor layers 2 located beneath are removed in the regions in which cut-outs 6 are present so that the material of the semiconductor layers 2 and of the second electrical contact 3 is removed beneath, above and to the right of the cut-outs 6. The individual regions between two photovoltaic elements A, B in which material was removed in this structuring step are linked so as to produce continuous insulation of the second contact of two adjoining regions A, B. This subsequently prevents two adjoining photovoltaic elements A, B from short-circuiting (FIGS. 3h, i)).

An Nd:YVO₄ laser from Rofin, of the RSY 20E SHG type, is employed as the laser for ablating the material from layers 2 and 3. The wavelength of the laser is 532 nm. This wavelength is specific to the ablation of materials of the two layers 2, 3. An average output power of 410 mW at a pulse repetition rate of 11 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted, from the substrate side, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm. This creates the approximately U-shaped insulations 9 around the cut-outs 6 and the contact bridges 8 for the punctiform series connection of the elements.

Because this structuring process P3 is again carried out along the entire stripe, a trench 7 is provided which is offset from the first trench 5. The structuring process P3 is repeated as often as the structuring processes P1 and P2 are, and as often as the number of layers 1, 2, 3 present in a plurality of stripe-shaped, parallel photovoltaic elements, separated by the trenches 5 and 7 and connected in series with one another by the cut-outs 6.

A cut-out 6 is required approximately every 1.5 millimeters for a surface area of 10×10 cm² and approximately 16 trenches 7.

The advantage of this exemplary embodiment, as compared to the prior art, is that a smaller surface area is required for the series connection, whereby greater conversion efficiency can be achieved. The distance of the holes 6 from one another is adjusted so that the overall losses caused by the interconnection, which result from the conducting losses caused by the electrical contact layers 1 and 3 and surface area losses caused by the material ablation and interconnection, are minimized.

### Fourth Exemplary Embodiment

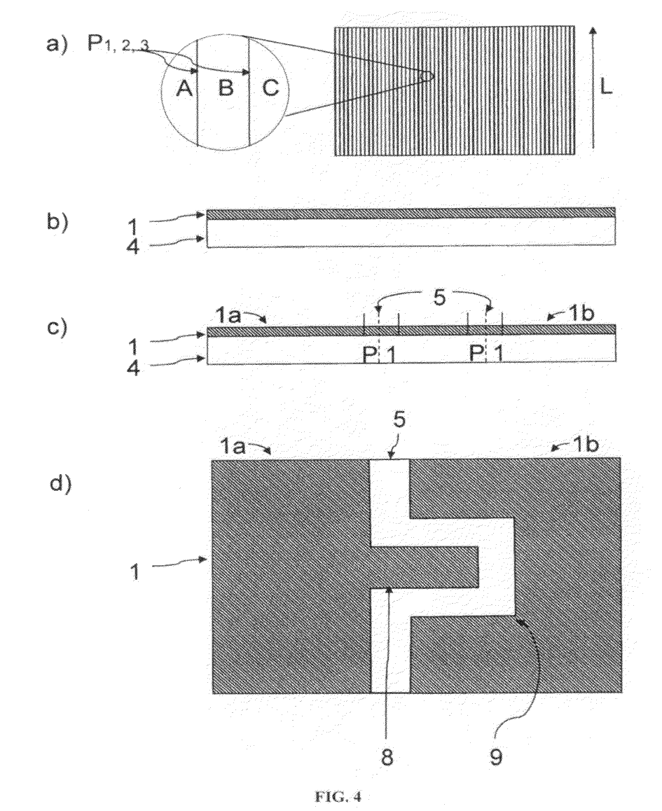

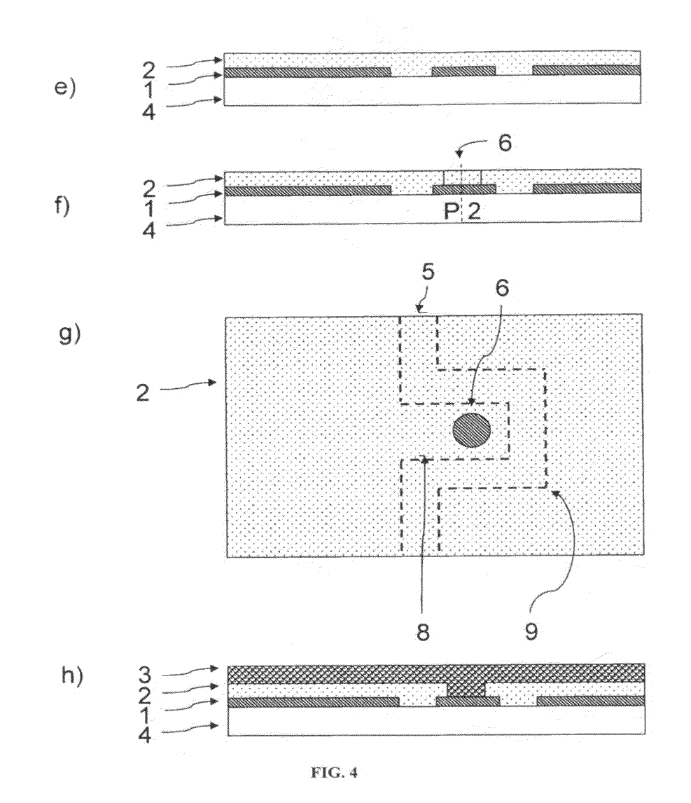

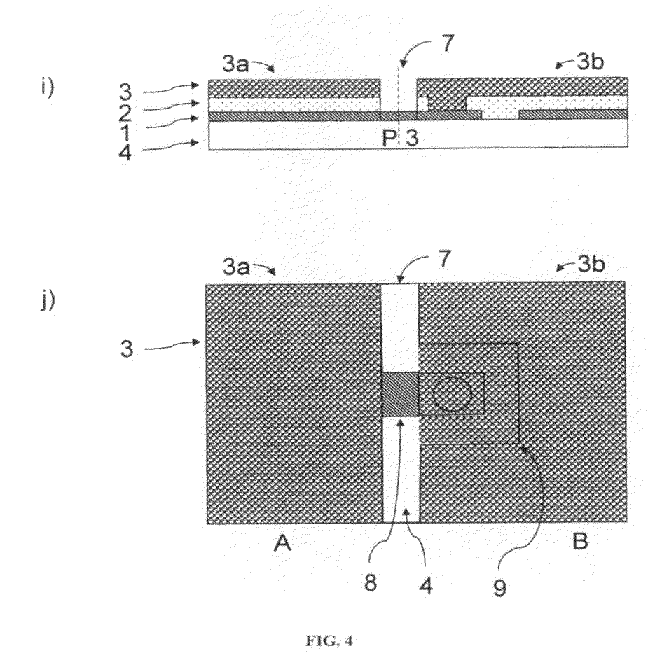

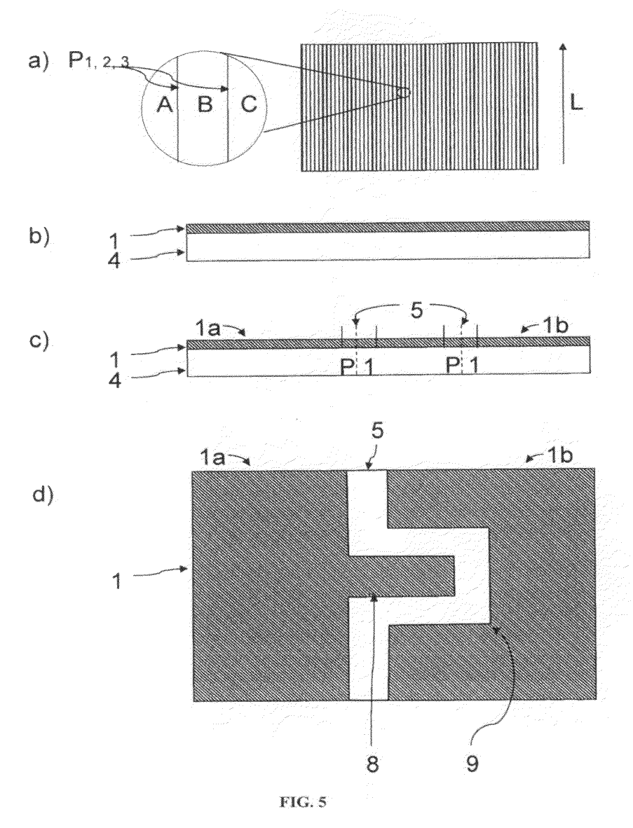

FIG. 4 shows the production and punctiform series connection of the photovoltaic elements A, B, C to form a functional solar module, in which the structuring of the active semiconductor layers 6 is provided in a punctiform manner within the regions 9 of the first structuring trenches 5, which are structured in a meander-shaped manner.

FIG. 4a) shows a top view of several stripe-shaped photovoltaic elements in a solar module. An enlarged detail shows the respective three stripes A, B, C disposed parallel to one another. The designations P1-3 in the figures denote the approximate positions and numbers of structurings of each trench or each punctiform semiconductor structuring. The stripe-shaped photovoltaic elements A, B, C are composed of the first and second electrical contact layers 1, 3 and the semiconductor layers 2 interposed between them.

FIG. 4b) shows the starting point of the method. A first electrical TCO (transparent conductive oxide) contact layer 1 is provided over the entire surface area of a superstrate 4, which serves as the substrate, having a thickness of approximately 1 millimeter.

Glass having a base area of 100 cm² has been selected as the substrate 4. The first electrical contact layer 1 comprising ZnO was deposited thereon in a first deposition process. A functional layer is provided between the substrate 4 and ZnO and is associated with the substrate (not shown) for improving the structuring of the ZnO.

A glass panel measuring 10×10 cm² is used as the base for the exemplary embodiment. A first electrical contact layer 1 comprising zinc oxide, which has been textured by way of a wet-chemical process and has a thickness of approximately 800 nm, is present on the glass substrate. In a first structuring process P1 (FIG. 4c)), material is removed from the first electrical contact layer 1 by way of laser ablation, whereby the surface of the substrate 4 is exposed in the treated regions 5. The laser beam is guided over the substrate in a meander-shaped manner, whereby contact bridges 8 are generated within the first electrical contact (FIG. 4d)). The U-shaped notches have a distance of 1.5 mm from one another. This structuring process P1 is carried out consecutively for all photovoltaic elements A, B, C. The laser is guided for this purpose over the surface of the substrate 4 using a relative movement. The distance and output power are adjusted so that material of the layers 1 is removed.

The laser that is employed is an Nd:YVO₄ laser from Rofin, of the RSY 20E THG type, having a wavelength of 355 nm. This wavelength is specific to the ablation of material of the contact layer 1. An average output power of 300 mW at a pulse repetition rate of 15 kHz is selected. The velocity of the relative movement between the laser beam and substrate is 250 mm/s. The duration of the individual pulses is approximately 13 ns. The laser radiation is focused on the layer side of the substrate 4 using a focusing unit that has a focal distance of 100 mm. To this end, the beam is conducted, from the substrate side, at the layer 1 to be ablated through the transparent substrate 4. The intensity distribution of the focused beam is substantially 2-dimensional, rotationally symmetrical and Gaussian, wherein each pulse produces a circular ablation having a diameter of approximately 35 μm. Following the first structuring process P1, the first electrical contact layer 1 is separated by parallel first trenches 5 down to the substrate 4. As a result, the stripe-shaped, parallel first electrical contact layers of the photovoltaic elements A, B, C are present on the substrate 4 electrically insulated from one another by the trenches 5. A plurality of first trenches 5 for separating the photovoltaic elements A, B, C are thus created (see FIG. 4a: vertical stripes in the module on the right).

Following the structuring process P1, a respective trench 5 comprising U-shaped notches is located between two directly adjoining photovoltaic elements A, B or C, B. The structuring process P1 is carried out by way of computer-assisted control. The structuring process P1 is repeated a number of times equal to the number of photovoltaic elements that are to be generated. For an edge length of the glass substrate 4 of 10×10 cm, approximately 16 parallel trenches 5 are formed, so that a stripe A, B, or C has a width of approximately 0.5 cm.

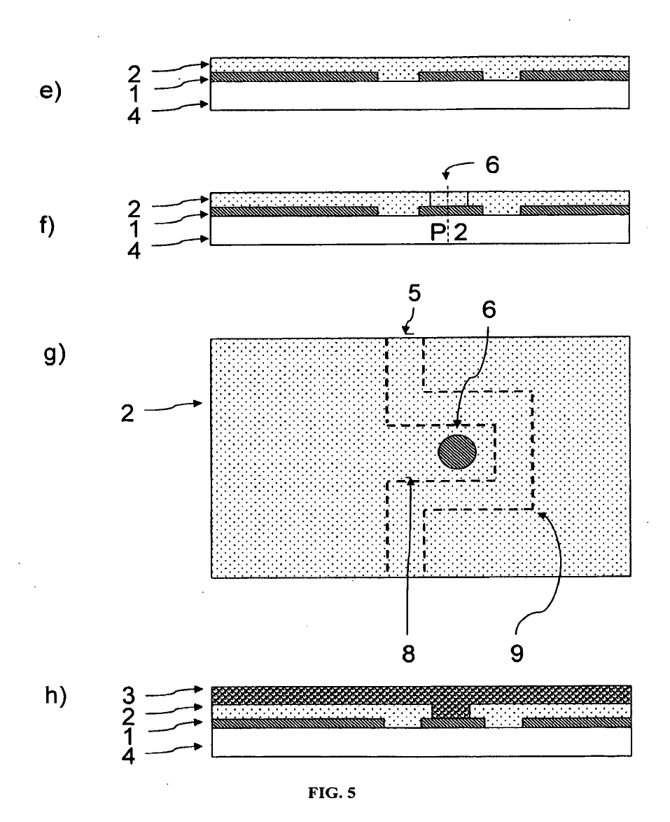

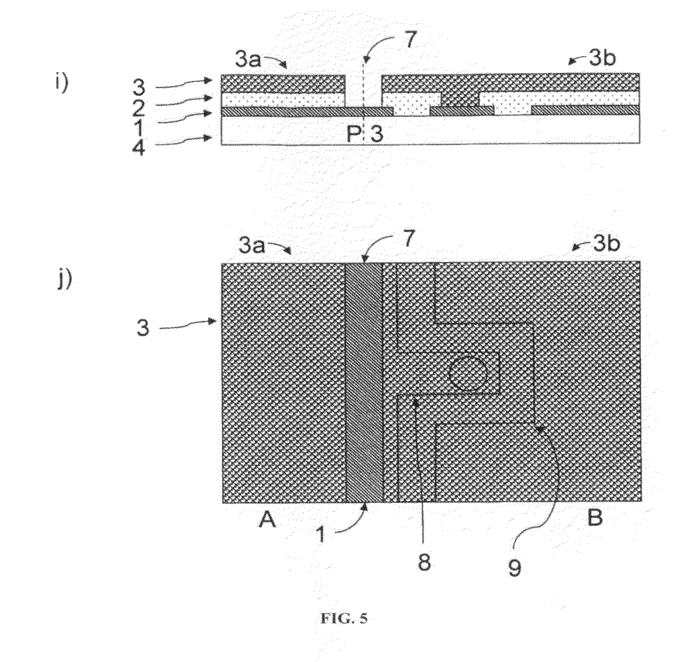

Thereafter, the entire substrate 4 is covered with a microcrystalline p-i-n solar cell 2 comprising silicon on the side on which the first electrical contact layer 1 is located, whereby the first electrical contact layer 1 and the trenches 5 are covered or filled with the silicon of the layers 2 (FIG. 5e)). The overall thickness of the microcrystalline p-i-n layer stack 2, which serves as the active semiconductor layer 2, is approximately 1300 nm.

The active semiconductor layers 2 are ablated up to the surface of the first electrical contact layer 1 (FIG. 5f)) by means of a second structuring process along the dotted line P2 so as to generate punctiform cut-outs 6. To this end, the punctiform cut-outs 6 are produced in the region of the contact bridges 8 (FIG. 5g)) so as to be able to generate punctiform contacts between adjoining photovoltaic elements, in the present case from element A to element B.

As differs from the first structuring process P1, no continuous ablation of the active semiconductor layers 2, creating a continuous trench up to the surface of the first electrical contact layer 1, is performed.

The laser that is employed is an Nd:YVO₄ laser from Rofin, of the RSY 20E SHG type. The wavelength of the laser is 532 nm. This wavelength is specific to the ablation of the materials of the semiconductor layers 2. Because both the substrate 4 and the first electrical contact layer 1 are highly transparent at the selected specific wavelength of 532 nm, selective ablation of the active semiconductor layers 2 is assured. The energy for each laser pulse is selected to be approximately 40 μJ. The pulse repetition rate is 533 Hz. The velocity of the relative movement between the laser beam and substrate is 800 mm/s. This results in a distance of the holes from each other of 1.5 millimeters. The duration of the individual pulses is approximately 13 ns. The laser radiation is focused on the layer side of the substrate 4 using a focusing unit that has a focal distance of 300 mm. To this end, the beam is conducted from the substrate side 4 through the transparent substrate 4 at the layer to be ablated. The intensity distribution of the focused beam is substantially 2-dimensional, rotationally symmetrical and Gaussian, wherein each pulse produces a circular ablation having a diameter of approximately 70 μm.

This results in the stripe-shaped, parallel photovoltaic elements A, B, C on the substrate 4, wherein punctiform cut-outs 6 exist in the subsequently active semiconductor layers 2 so as to implement a punctiform series connection. A plurality of openings 6 for contacting the first electrical contact layer 1 of the photovoltaic elements A, B, C are thus generated. The structuring process P2 is repeated a number of times equal to the number of photovoltaic elements that are present.

Then, a second electrical contact 3 is applied. The second electrical contact 3 is provided on the active semiconductor layer 2. A layer system comprising 80 nm of zinc oxide in combination with a 200 nm thick silver layer is selected as the second electrical contact layer 3. Here, first the zinc oxide layer, followed by the silver layer, are present on the silicon layer stack 2 on the side of the second electrical contact layer (FIG. 4h)).

A structuring process P3 then follows. The trenches 7, which were produced by the structuring process P3, are generated so that the second electrical contact layer 3 and the active semiconductor layers 2 located beneath are removed at the location of the first trenches 5 at those sites at which no cut-out 6 for contacting the first electrical contact layer and no contact bridge 8 are present.

Moreover, the trenches 7 are continued in the regions of the contact bridges 8 in a rectilinear fashion, whereby the electrical contact layer 3 and the active semiconductor layers located beneath are removed and the first electrical contact 1 located beneath is exposed (FIGS. 4i, j)). The rectilinear trench 7 creates continuous insulation of the second electrical contact of two adjoining regions A, B. This subsequently prevents two adjoining photovoltaic elements A, B from short-circuiting.

An Nd:YVO₄ laser from Rofin, of the RSY 20E SHG type, is employed as the laser for ablating the material from layers 2 and 3. The wavelength of the laser is 532 nm. This wavelength is specific to the ablation of materials of the two layers 2, 3. An average output power of 410 mW at a pulse repetition rate of 11 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted, from the substrate side, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm.

Because this structuring process P3 is again carried out along the entire stripe, a trench 7 is provided which is located partially on the first trench 5. The structuring process P3 is repeated as often as the structuring processes P1 and P2 are, and as often as the number of layers 1, 2, 3 present in a plurality of stripe-shaped, parallel photovoltaic elements, separated by the trenches 5 and 7 and connected in series with one another by the cut-outs 6.

A cut-out 6 is required approximately every 1.5 millimeters for a surface area of 10×10 cm² and approximately 16 trenches 7.

The advantage of this exemplary embodiment, as compared to the prior art, is that a smaller surface area is required for the series connection, whereby greater conversion efficiency can be achieved. The distance of the holes 6 from one another is adjusted so that the overall losses caused by the interconnection, which result from the conducting losses caused by the electrical contact layers 1 and 3 and surface area losses caused by the material ablation and interconnection, are minimized.

### Fifth Exemplary Embodiment

FIG. 5 shows the production and punctiform series connection of the photovoltaic elements A, B, C to form a functional solar module, in which the structuring of the active semiconductor layers 6 is provided in a punctiform manner within the regions 9 of the first structuring trenches 5 which are structured in a meander-shaped manner.

FIG. 5a) shows a top view of several stripe-shaped photovoltaic elements in a solar module. An enlarged detail shows the respective three stripes A, B, C disposed parallel to one another. The designations P1-3 in the figures denote the approximate positions and numbers of structurings of each trench or each punctiform semiconductor structuring. The stripe-shaped photovoltaic elements A, B, C are composed of the first and second electrical contact layers 1, 3 and the semiconductor layers 2 interposed between them.

FIG. 5b) shows the starting point of the method. A first electrical TCO (transparent conductive oxide) contact layer 1 is provided over the entire surface area of a superstrate 4, which serves as the substrate, having a thickness of approximately 1 millimeter.

Glass having a base area of 100 cm² has been selected as the substrate 4. The first electrical contact layer 1 comprising ZnO was deposited thereon in a first deposition process. A functional layer is provided between the substrate 4 and ZnO and is associated with the substrate (not shown) for improving the structuring of the ZnO.

A glass panel measuring 10×10 cm² is used as the base for the exemplary embodiment. A first electrical contact layer 1 comprising zinc oxide, which has been textured by way of a wet-chemical process and has a thickness of approximately 800 nm, is present on the glass substrate.

In a first structuring process P1 (FIG. 5c)), material is removed from the first electrical contact layer 1 by way of laser ablation, whereby the surface of the substrate 4 is exposed in the treated regions 5. The laser beam is guided over the substrate in a meander-shaped manner, whereby contact bridges 8 are generated within the first electrical contact (FIG. 5d)). The U-shaped notches have a distance of 1.5 mm from one another. This structuring process P1 is carried out consecutively for all photovoltaic elements A, B, C. The laser is guided for this purpose over the surface of the substrate 4 using a relative movement. The distance and output power are adjusted so that material of the layers 1 is removed.

An Nd:YVO₄ laser from Rofin, of the RSY 20E THG type, having a wavelength of 355 nm is selected as the laser. This wavelength is specific to the ablation of material of the contact layer 1. An average output power of 300 mW at a pulse repetition rate of 15 kHz is selected. The velocity of the relative movement between the laser beam and substrate is 250 mm/s. The duration of the individual pulses is approximately 13 ns. The laser radiation is focused on the layer side of the substrate 4 using a focusing unit that has a focal distance of 100 mm. To this end, the beam is conducted, from the substrate side, at the layer 1 to be ablated through the transparent substrate 4. The intensity distribution of the focused beam is substantially 2-dimensional, rotationally symmetrical and Gaussian, wherein each pulse produces a circular ablation having a diameter of approximately 35 μm. Following the first structuring process P1, the first electrical contact layer 1 is separated by parallel first trenches 5 down to the substrate 4. As a result, the stripe-shaped, parallel first electrical contact layers of the photovoltaic elements A, B, C are present on the substrate 4 electrically insulated from one another by the trenches 5. A plurality of first trenches 5 for separating the photovoltaic elements A, B, C are thus created (see FIG. 5a: vertical stripes in the module on the right).

Following the structuring process P1, a respective trench 5 comprising U-shaped notches is located between two directly adjoining photovoltaic elements A, B or C, B. The structuring process P1 is carried out by way of computer-assisted control. The structuring process P1 is repeated a number of times equal to the number of photovoltaic elements that are to be generated. For an edge length of the glass substrate 4 of 10×10 cm, approximately 16 parallel trenches 5 are generated, so that a stripe A, B, or C has a width of approximately 0.5 cm.

Thereafter, the entire substrate 4 is covered with a microcrystalline p-i-n solar cell 2 comprising silicon on the side on which the first electrical contact layer 1 is located, whereby the first electrical contact layer 1 and the trenches 5 are covered or filled with the silicon of the layers 2 (FIG. 5e)). The overall thickness of the microcrystalline p-i-n layer stack 2, which serves as the active semiconductor layer 2, is approximately 1300 nm.

The active semiconductor layers 2 are ablated up to the surface of the first electrical contact layer 1 (FIG. 5f)) by means of a second structuring process along the dotted line P2 so as to generate punctiform cut-outs. To this end, the punctiform cut-outs 6 are produced in the region of the contact bridges 8 (FIG. 5g)) so as to be able to generate punctiform contacts between adjoining photovoltaic elements, in the present case from element A to element B.

As differs from the first structuring process P1, no continuous ablation of the active semiconductor layers 2, creating a continuous trench up to the surface of the first electrical contact layer 1, is performed. The laser that is employed is an Nd:YVO₄ laser from Rofin, of the RSY 20E SHG type. The wavelength of the laser is 532 nm. This wavelength is specific to the ablation of the materials of the semiconductor layers 2. Because both the substrate 4 and the first electrical contact layer 1 are highly transparent at the selected specific wavelength of 532 nm, selective ablation of the active semiconductor layers 2 is assured. The energy for each laser pulse is selected to be approximately 40 μJ. The pulse repetition rate is 533 Hz. The velocity of the relative movement between the laser beam and substrate is 800 mm/s. This results in a distance of the cut-outs from each other of 1.5 millimeters. The duration of the individual pulses is approximately 13 ns. The laser radiation is focused on the layer side of the substrate 4 using a focusing unit that has a focal distance of 300 mm. To this end, the beam is conducted, from the substrate side 4, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm.

This results in the stripe-shaped, parallel photovoltaic elements A, B, C on the substrate 4, wherein punctiform cut-outs 6 exist in the subsequently active semiconductor layers 2 so as to implement a punctiform series connection. A plurality of openings 6 for contacting the first electrical contact layer 1 of the photovoltaic elements A, B, C are thus generated. The structuring process P2 is repeated a number of times equal to the number of photovoltaic elements that are present.

Then, a second electrical contact 3 is applied. The second electrical contact 3 is provided on the active semiconductor layer 2. A layer system comprising 80 nm of zinc oxide in combination with a 200 nm thick silver layer is selected as the second electrical contact layer 3. Here, first the zinc oxide layer, followed by the silver layer, are present on the silicon layer stack 2 on the side of the second electrical contact layer (FIG. 5h)).

A structuring process P3 then follows. The trenches 7, which were produced by the structuring process P3, are generated so that the second electrical contact layer 3 and the active semiconductor layers 2 located beneath are removed offset from the location of the first trenches 5 in a rectilinear manner, which is to say no meander-shaped ablation of the layers 2 and 3 is performed. The offset of the trenches 7 with respect to the non-meandering regions of the trenches 5 is in the direction in which the cut-outs 6 are not located (FIGS. 5i, j)). The offset is approximately 150 μm. The process is carried out so as to expose the first electrical contact 1. The rectilinear trench 7 creates continuous insulation of the second electrical contact of two adjoining regions A, B. This subsequently prevents two adjoining photovoltaic elements A, B from short-circuiting.

An Nd:YVO₄ laser from Rofin, of the RSY 20E SHG type, is employed as the laser for ablating the material from layers 2 and 3. The wavelength of the laser is 532 nm. This wavelength is specific to the ablation of materials of the two layers 2, 3. An average output power of 410 mW at a pulse repetition rate of 11 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted, from the substrate side, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm.

This structuring process P3 is again carried out along the entire stripe. The structuring process P3 is repeated as often as the structuring processes P1 and P2 are, and as often as the number of layers 1, 2, 3 present in a plurality of stripe-shaped, parallel photovoltaic elements, separated by the trenches 5 and 7 and connected in series with one another by the cut-outs 6.

A cut-out 6 is required approximately every 1.5 millimeters for a surface area of 10×10 cm² and approximately 16 trenches 7.

The advantage of this exemplary embodiment, as compared to the prior art, is that a smaller surface area is required for the series connection, whereby greater conversion efficiency can be achieved. The distance of the holes 6 from one another is adjusted so that the overall losses caused by the interconnection, which result from the conducting losses caused by the electrical contact layers 1 and 3 and surface area losses caused by the material ablation and interconnection, are minimized.

### Sixth Exemplary Embodiment

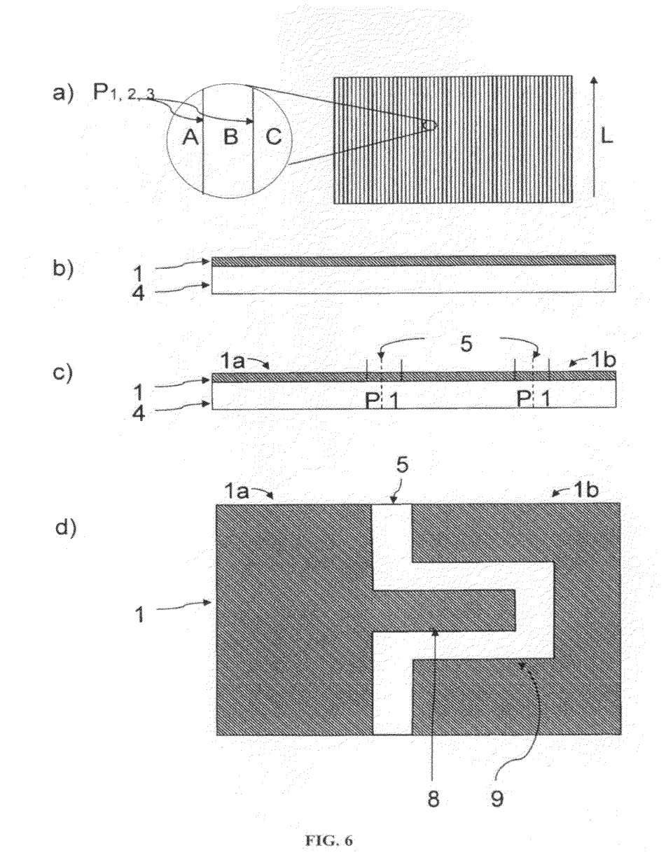

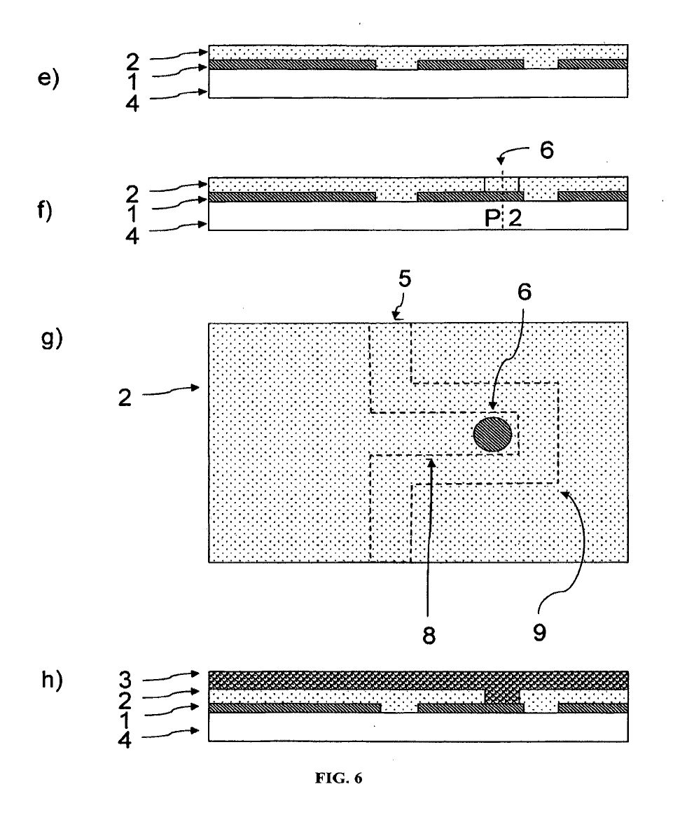

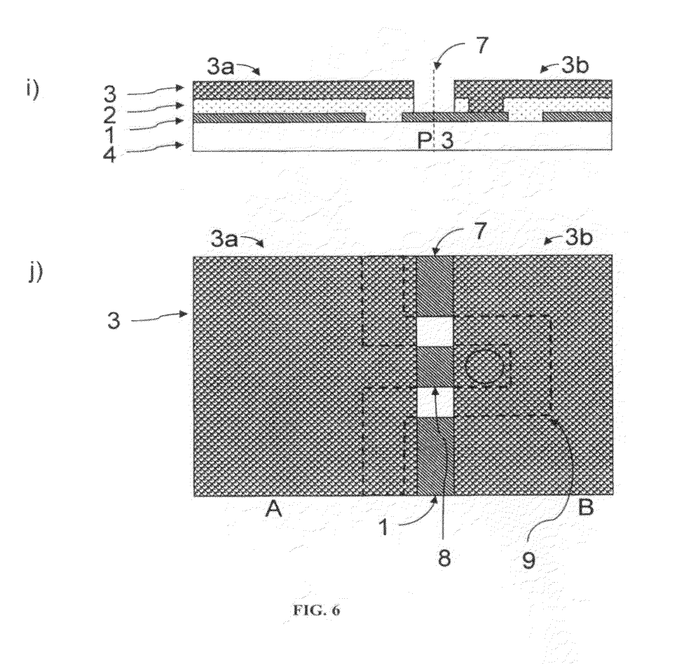

FIG. 6 shows the production and punctiform series connection of the photovoltaic elements A, B, C to form a functional solar module, in which the structuring of the active semiconductor layers 6 is provided in a punctiform manner within the regions 9 of the first structuring trenches 5 which are structured in a meander-shaped manner.

FIG. 6a) shows a top view of a several stripe-shaped photovoltaic elements in a solar module. An enlarged detail shows the respective three stripes A, B, C disposed parallel to one another. The designations P1-3 in the figures denote the approximate positions and numbers of structurings of each trench or each punctiform semiconductor structuring. The stripe-shaped photovoltaic elements A, B, C are composed of the first and second electrical contact layers 1, 3 and the semiconductor layers 2 interposed between them.

FIG. 6b) shows the starting point of the method. A first electrical TCO (transparent conductive oxide) contact layer 1 is provided over the entire surface area of a superstrate 4, which serves as the substrate, having a thickness of approximately 1 millimeter.

Glass having a base area of 100 cm² has been selected as the substrate 4. The first electrical contact layer 1 comprising ZnO was deposited thereon in a first deposition process. A functional layer is provided between the substrate 4 and ZnO and is associated with the substrate (not shown) for improving the structuring of the ZnO.

A glass panel measuring 10×10 cm² is used as the base for the exemplary embodiment. A first electrical contact layer 1 comprising zinc oxide, which has been textured by way of a wet-chemical process and has a thickness of approximately 800 nm, is present on the glass substrate.

In a first structuring process P1 (FIG. 6c)), material is removed from the first electrical contact layer 1 by way of laser ablation, whereby the surface of the substrate 4 is exposed in the treated regions 5. The laser beam is guided over the substrate in a meander-shaped manner, whereby contact bridges 8 are generated within the first electrical contact (FIG. 6d)). The U-shaped notches have a distance of 1.5 mm from one another. This structuring process P1 is carried out consecutively for all photovoltaic elements A, B, C. The laser is guided for this purpose over the surface of the substrate 4 using a relative movement. The distance and output power are adjusted so that material of the layers 1 is removed.

The laser that is employed is an Nd:YVO₄ laser from Rofin, of the RSY 20E THG type, having a wavelength of 355 nm. This wavelength is specific to the ablation of material of the contact layer 1. An average output power of 300 mW at a pulse repetition rate of 15 kHz is selected. The velocity of the relative movement between the laser beam and substrate is 250 mm/s. The duration of the individual pulses is approximately 13 ns. The laser radiation is focused on the layer side of the substrate 4 using a focusing unit that has a focal distance of 100 mm. To this end, the beam is conducted, from the substrate side, at the layer 1 to be ablated through the transparent substrate 4. The intensity distribution of the focused beam is substantially 2-dimensional, rotationally symmetrical and Gaussian, wherein each pulse produces a circular ablation having a diameter of approximately 35 μm. Following the first structuring process P1, the first electrical contact layer 1 is separated by parallel first trenches 5 down to the substrate 4. As a result, the stripe-shaped, parallel first electrical contact layers of the photovoltaic elements A, B, C are present on the substrate 4 electrically insulated from one another by the trenches 5. A plurality of first trenches 5 for separating the photovoltaic elements A, B, C are thus created (see FIG. 6a: vertical stripes in the module on the right).

Following the structuring process P1, a respective trench 5 comprising U-shaped notches is located between two directly adjoining photovoltaic elements A, B or C, B. The structuring process P1 is carried out by way of computer-assisted control. The structuring process P1 is repeated a number of times equal to the number of photovoltaic elements that are to be generated. For an edge length of the glass substrate 4 of 10×10 cm, approximately 16 parallel trenches 5 are formed, so that a stripe A, B, or C has a width of approximately 0.5 cm.

Thereafter, the entire substrate 4 is covered with a microcrystalline p-i-n solar cell 2 comprising silicon on the side on which the first electrical contact layer 1 is located, whereby the first electrical contact layer 1 and the trenches 5 are covered or filled with the silicon of the layers 2 (FIG. 6e)). The overall thickness of the microcrystalline p-i-n layer stack 2, which serves as the active semiconductor layer 2, is approximately 1300 nm.

The active semiconductor layers 2 are ablated up to the surface of the first electrical contact layer 1 (FIG. 6f)) by means of a second structuring process along the dotted line P2 so as to generate punctiform cut-outs. To this end, the punctiform cut-outs 6 are produced in the region of the contact bridges 8 (FIG. 6g)) so as to be able to generate punctiform contacts between adjoining photovoltaic elements, in the present case from element A to element B.

As differs from the first structuring process P1, no continuous ablation of the active semiconductor layers 2, creating a continuous trench up to the surface of the first electrical contact layer 1, is performed.

The laser that is employed is an Nd:YVO₄ laser from Rofin, of the RSY 20E SHG type. The wavelength of the laser is 532 nm. This wavelength is specific to the ablation of the materials of the semiconductor layers 2. Because both the substrate 4 and the first electrical contact layer 1 are highly transparent at the selected specific wavelength of 532 nm, selective ablation of the active semiconductor layers 2 is assured. The energy for each laser pulse is selected to be approximately 40 μJ. The pulse repetition rate is 533 Hz. The velocity of the relative movement between the laser beam and substrate is 800 mm/s. This results in a distance of the holes from each other of 1.5 millimeters. The duration of the individual pulses is approximately 13 ns. The laser radiation is focused on the layer side of the substrate 4 using a focusing unit that has a focal distance of 300 mm. To this end, the beam is conducted, from the substrate side 4, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm.

This results in the stripe-shaped, parallel photovoltaic elements A, B, C on the substrate 4, wherein punctiform cut-outs 6 exist in the subsequently active semiconductor layers 2 so as to implement a punctiform series connection. A plurality of openings 6 for contacting the first electrical contact layer 1 of the photovoltaic elements A, B, C are thus generated. The structuring process P2 is repeated a number of times equal to the number of photovoltaic elements that are present.

Then, a second electrical contact 3 is applied. The second electrical contact 3 is provided on the active semiconductor layer 2. A layer system comprising 80 nm of zinc oxide in combination with a 200 nm thick silver layer is selected as the second electrical contact layer 3. Here, first the zinc oxide layer, followed by the silver layer, are present on the silicon layer stack 2 on the side of the second electrical contact layer (FIG. 6h)).

A structuring process P3 then follows. The trenches 7, which were produced by the structuring process P3, are generated so that the second electrical contact layer 3 and the active semiconductor layers 2 located beneath are removed offset from the location of the first trenches 5 in a rectilinear manner, which is to say no meander-shaped ablation of the layers 2 and 3 is performed. Moreover, the second electrical contact 3 and the semiconductor layer 2 are removed as a result of the trenches 7 in the region of the contact bridges 8 as well as in the trenches 5 above and beneath the contact bridges 8 (FIG. 6i, j)). The offset of the trenches 7 with respect to the non-meandering regions of the trenches 5 is in the direction in which the cut-outs 6 are located. The offset is selected so that the trenches 7 are located between the non-meandering regions of the trenches 5 and the cut-outs 6. The rectilinear trench 7 created continuous insulation of the second electrical contact of two adjoining regions A, B. This subsequently prevents two adjoining photovoltaic elements A, B from short-circuiting.

An Nd:YVO₄ laser from Rofin, of the RSY 20E SHG type, is employed as the laser for ablating the material from layers 2 and 3. The wavelength of the laser is 532 nm. This wavelength is specific to the ablation of materials of the two layers 2, 3. An average output power of 410 mW at a pulse repetition rate of 11 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted, from the substrate side, at the layer to be ablated, through the transparent substrate 4. The intensity distribution of the focused beam is substantially 2-dimensional, rotationally symmetrical and Gaussian, wherein each pulse produces a circular ablation having a diameter of approximately 70 μm.

This structuring process P3 is again carried out along the entire stripe. The structuring process P3 is repeated as often as the structuring processes P1 and P2 are, and as often as the number of layers 1, 2, 3 present in a plurality of stripe-shaped, parallel photovoltaic elements, separated by the trenches 5 and 7 and connected in series with one another by the cut-outs 6.

A cut-out 6 is required approximately every 1.5 millimeters for a surface area of 10×10 cm² and approximately 16 trenches 7.

The advantage of this exemplary embodiment, as compared to the prior art, is that a smaller surface area is required for the series connection, whereby greater conversion efficiency can be achieved. The distance of the holes 6 from one another is adjusted so that the overall losses caused by the interconnection, which result from the conducting losses caused by the electrical contact layers 1 and 3 and surface area losses caused by the material ablation and interconnection, are minimized.

Within the spirit of the invention, none of the method steps described in the exemplary embodiments shall be construed to be of a limiting nature. In particular, the dimensions of the trenches and of the contact points, as well as the distances between the trenches and between the points and between trenches and points, the layer materials of the layers of the photovoltaic elements as such, and the composition of the contact material, shall not result in any restriction of the invention.

1. A method for producing, and for connecting in series, stripe-shaped elements on a substrate, in which a plurality of stripe-shaped first electrical contact layers are generated on the substrate, which are insulated in a stripe-shaped manner over the length of the elements by first trenches up to the surface of the substrate, and for providing semiconductor layers on the stripe-shaped first electrical contact layers or in the first trenches, wherein:
the semiconductor layers are designed with regional cut-outs at an edge of each first trench in which the surface of the first electrical contact layers is exposed;
and a plurality of stripe-shaped second electrical contact layers are provided on the semiconductor layers, whereby the cut-outs are filled and regional contacts of the second electrical contact layer of an element to the first electrical contact layer of an adjoining element are established;
wherein the second trenches are created over the length of the elements in the second electrical contact layers so as to insulate the same; and
either meandering sections of the first trenches are generated around the cut-out so as to insulate the first electrical contact layers and/or meandering sections of the second trenches are generated around the cut-out so as to insulate the second electrical contact layers.

2. A method according to claim 1, wherein the number of meandering sections of the first or second trenches corresponds to the number of cut-outs.

3. A method according to claim 1, wherein a second trench that is associated with a first trench is generated so as to create the stripe-shaped elements.

4. A method according to claim 1, comprising selecting a distance of the cut-outs from each other of 0.2 millimeters to 100 millimeters, and more particularly 1.5 millimeters to 10 millimeters along the edge of a first trench.

5. A method according to claim 1, wherein there is a lateral distance of up to 2 mm between a first trench and a second trench so as to insulate adjoining contact layers.

6. A method according to claim 1, wherein except in the region of the cut-outs, the second trenches are provided directly above the first trenches so that the sections of the first or second trenches running over the length of the elements are generated without lateral offset.

7. A method according to claim 1, wherein the regional cut-outs are preferably produced to have a surface area of up to 1 mm², and more particularly up to 0.01 mm².

8. A method according to claim 1, wherein laser ablation is provided for generating the first and/or second trenches and/or the cut-outs.

9. A method according to claim 1, wherein the arrangement of masks is provided for producing the first and/or second trenches and/or the cut-outs.

10. A method according to claim 1, wherein a PVD or CVD method or a spraying method or an (ink jet) printing method is provided for depositing layers.

11. A method according to claim 1, wherein an etching method is provided for producing the first and/or second trenches and/or the cut-outs.

12. A method according to claim 1, comprising selecting materials for the semiconductor layers and for the contact layers, so that these create photovoltaic elements over the length of the substrate.

13. A method according to claim 1, comprising selecting a glass substrate.

14. A method according to claim 1, comprising selecting a TCO (transparent conductive oxide) as the material for the first electrical contact layers on the substrate.

15. A method according to claim 1, comprising applying at least one n-i-p or p-i-n structure as the active semiconductor layers to the first electrical contact layers

16. A method according to claim 1, comprising selecting ZnO/Ag as the material for the second electrical contact layers.

17. A layer structure comprising a substrate, comprising a plurality of stripe-shaped first electrical contact layers over the length of the substrate and semiconducting layers, which are provided on the first electrical contact layers, and further a plurality of stripe-shaped second electrical contact layers over the length of the substrate, which are provided on the semiconducting layers, the second electrical contact layers make contact with the first electrical contact layers by way of regional cut-outs in the semiconducting layers, and first trenches are provided in the first electrical contact layers and second trenches are provided in the second electrical contact layers so as to insulate the first and second electrical contact layers, with the first and/or second trenches being guided around the cut-outs in a meandering manner.

18. The layer structure according to claim 17, wherein the regional cut-outs are created between a first trench and a second trench.

19. The layer structure according to claim 17, wherein, with the exception of meandering sections, the first and second trenches over the length of the elements are created without, or with only minor, lateral offset from one another.

20. A solar module as a layer structure according claim 17, wherein the second electrical contact layers and first electrical contact layers and the semiconducting layers comprise materials that create photovoltaic elements over the length of the substrate.

21. The solar module according to claim 20, wherein the ratio of the surface area of the active semiconductor layers to the total surface area of the module is at least 98%, preferably more than 98.5%, and more particularly 99% or more.

22. A method for producing, and for connecting in series, stripe-shaped elements on a substrate, in which a plurality of stripe-shaped first electrical contact layers are generated on the substrate, which are insulated in a stripe-shaped manner over the length of the elements by first trenches up to the surface of the substrate, and for providing semiconductor layers on the stripe-shaped first electrical contact layers or in the first trenches, and in which a plurality of stripe-shaped second electrical contact layers are provided on the semiconductor layers, the second trenches being created over the length of the elements in the second electrical contact layers so as to insulate the same, the semiconductor layers are provided with regional cut-outs at a respective edge of each of the first trenches, so that the second electrical contact layers can make contact therein with the first electrical contact layers via the regional cut outs so as to connect adjoining elements in series.
